(19) United States
(12) Patent Application Publication
(10) Pub. No.: US 2023/0341762 A1
(43) Pub. Date: Oct. 26, 2023

(54) PRINT ELEMENT SUBSTRATE AND METHOD FOR MANUFACTURING PRINT ELEMENT SUBSTRATE

(71) Applicant: CANON KABUSHIKI KAISHA, Tokyo (JP)

(72) Inventors: KEIJI MATSUMOTO, Kanagawa (JP); KAZUHIRO ASAI, Kanagawa (JP)

(21) Appl. No.: 18/303,077

(22) Filed: Apr. 19, 2023

(30) Foreign Application Priority Data
Apr. 21, 2022 (JP) 2022-069953

(51) Int. Cl. G03F 1/60; G03F 7/038; G03F 1/48; G03F 7/20; G03F 7/00

(52) U.S. Cl. CPC G03F 1/60; G03F 1/48; G03F 7/001; G03F 7/0382; G03F 7/70358; G03F 7/70675; G03F 7/70808

(57) ABSTRACT

A print element substrate including a substrate having an energy generating element that generates energy for ejecting liquid from an ejection port and a flow passage forming member including a flow passage that supplies the liquid to the ejection port, wherein the flow passage forming member includes a cavity not communicating with the flow passage, and a side surface of the cavity is formed substantially perpendicular to the substrate wherein a base film is formed between the cavity and the substrate. The refractive index of the flow passage forming member is lower than the refractive index of the base film, and the difference between the refractive index of the flow passage forming member and the refractive index of the base film is greater than or equal to 0.3.

### BACKGROUND

### Field of the Disclosure

The present disclosure relates to a print element substrate and a method for manufacturing the print element substrate.

### Description of the Related Art

Japanese Patent Laid-Open No. 2011-68129 describes a method for providing individual identification information in a print element substrate. According to the method, a cavity is provided in a flow passage forming member that forms a flow passage on the print element substrate such that the shape of the cavity (a cavity pattern) represents, for example, a number indicating the individual identification information. Furthermore, according to Japanese Patent Laid-Open No. 2011-68129, the visibility of the individual identification information is improved by tilting the side surface of the cavity with respect to the substrate.

However, in the method described in Japanese Patent Laid-Open No. 2011-68129, since the side surface of the cavity is tilted with respect to the substrate, it is difficult to reduce the size of the print element substrate. This is because, to tilt the side surface of the cavity, an extra space corresponding to the amount of tilt of the side surface is required between adjacent pieces of individual identification information, making it difficult to densely pack the cavity pattern.

### SUMMARY OF THE DISCLOSURE

Accordingly, the present disclosure provides a print element substrate and a manufacturing process of the print element substrate capable of ensuring both the visibility of individual identification information and reduction in size.

A liquid ejection head has been developed that performs printing by ejecting liquid onto a printing medium, such as printing paper. The liquid ejection head includes a print element substrate having ejection ports for ejecting liquid, energy generating elements for generating energy for ejection, and the like. From the viewpoint of production control, the print element substrate may be provided with individual identification information.

According to an aspect of the present disclosure, a print element substrate includes a substrate including an energy generating element configured to generate energy for ejecting liquid from an ejection port and a flow passage forming member including a flow passage configured to supply the liquid to the ejection port. The flow passage forming member includes a cavity not communicating with the flow passage. A side surface of the cavity is formed substantially perpendicular to the substrate. A base film is formed between the cavity and the substrate. The refractive index of the flow passage forming member is lower than the refractive index of the base film, and the difference between the refractive index of the flow passage forming member and the refractive index of the base film is greater than or equal to 0.3.

Further features of the present disclosure will become apparent from the following description of exemplary embodiments with reference to the attached drawings.

### BRIEF DESCRIPTION OF THE DRAWINGS

FIG. 1 is a schematic illustration of a print element substrate, according to one or more aspect and/or embodiment of the subject disclosure.

FIG. 2 is a schematic cross-sectional view of the print element substrate, according to one or more aspect and/or embodiment of the subject disclosure.

FIG. 3 is a top view of an individual identification information section, according to one or more aspect and/or embodiment of the subject disclosure.

FIG. 4A illustrates a process of forming a liquid supply port in a substrate provided with a base film, according to one or more aspect and/or embodiment of the subject disclosure; FIG. 4B illustrates a process of forming a first flow passage forming member in the substrate, according to one or more aspect and/or embodiment of the subject disclosure; FIG. 4C illustrates an i-line exposure process performed on the first flow passage forming member through a photomask, according to one or more aspect and/or embodiment of the subject disclosure; FIG. 4D illustrates a process of forming a second flow passage forming member on the first flow passage forming member, according to one or more aspect and/or embodiment of the subject disclosure; FIG. 4E illustrates an i-line exposure process performed on the second flow passage forming member through a photomask, according to one or more aspect and/or embodiment of the subject disclosure; and FIG. 4F illustrates a process of removing a portion light-shielded by the photomask with a solvent, according to one or more aspect and/or embodiment of the subject disclosure.

FIG. 5 is a top view of individual identification information, according to one or more aspect and/or embodiment of the subject disclosure.

FIG. 6 illustrates Fresnel reflection, according to one or more aspect and/or embodiment of the subject disclosure.

FIG. 7A is a top view of characters having shapes that can be seen from above; and FIG. 7B is a cross-sectional view of marks having shapes that can be seen from above, both according to one or more aspect and/or embodiment of the subject disclosure.

### DESCRIPTION OF THE EMBODIMENTS

Embodiments of the present disclosure are described in detail below.

### First Embodiment

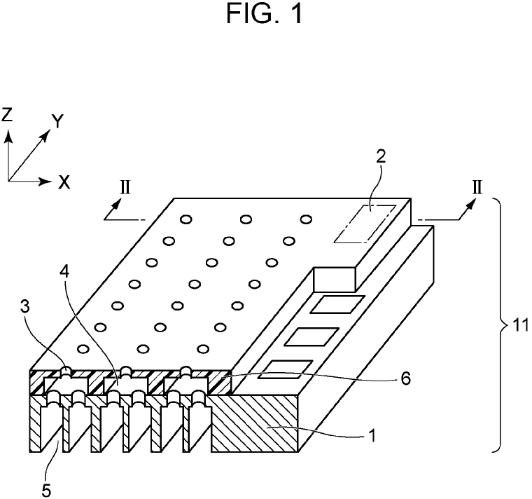

FIG. 1 is a schematic illustration of a print element substrate 11 according to the present embodiment. The print element substrate 11 includes a substrate 1 having an energy generating element (not illustrated) that generates energy for ejection and liquid supply ports 5. The print element substrate 11 further includes a flow passage forming member 6 formed on the substrate 1. The flow passage forming member 6 includes flow passages 4 and ejection ports 3. The print element substrate 11 has an individual information region 2 having a cavity 7 that does not communicate with the flow passages 4 in the flow passage forming member 6. The print element substrate 11 has a liquid-repellent film (not illustrated) on the positive Z direction surface thereof that serves as a liquid ejection surface.

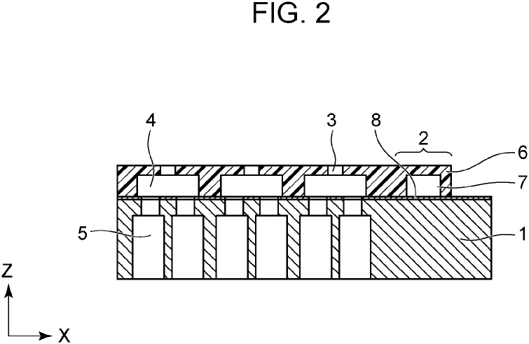

FIG. 2 is a schematic cross-sectional view taken along line II - II of the print element substrate illustrated in FIG. 1 according to the present embodiment. As illustrated in FIG. 2, the flow passage forming member 6 including the ejection ports 3 and the flow passages 4 is formed on a substrate 1 including an energy generating element (not illustrated). In addition, the liquid supply ports 5 are formed in the substrate 1 so as to pass through the flow passage forming member 6 from one surface to the other surface of the flow passage forming member 6. The flow passage forming member 6 has the individual information region 2 including the cavity 7 that does not communicate with the flow passage 4, and a base film 8 is formed on the substrate 1 in the cavity 7.

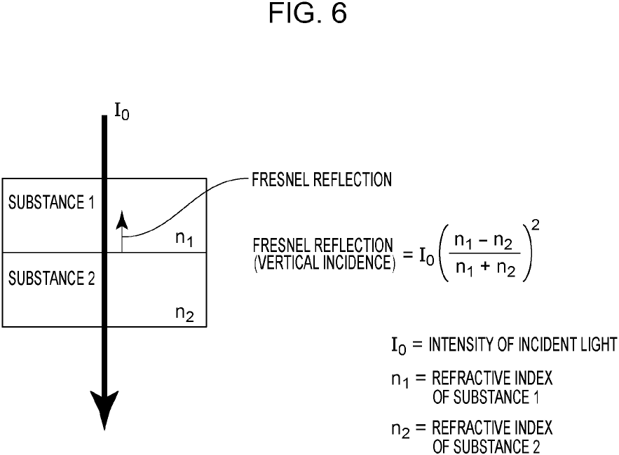

The base film 8 has a higher refractive index than the flow passage forming member 6, so that the visibility of the cavity 7 can be improved. FIG. 6 is a schematic illustration of Fresnel reflection (vertical incidence). As illustrated in FIG. 6, according to the Fresnel reflection formula when light is vertically incident on a boundary plane at which substances with different refractive indices are in contact with each other, the magnitude of the reflection is correlated with the difference between the refractive indices. According to the present embodiment, considering reflection at two boundary planes between the cavity 7 and the base film 8 and between the flow passage forming member 6 and the base film 8, it is desirable that the base film 8 have a higher refractive index than the flow passage forming member 6. The base film 8 can be located on the substrate surrounding the cavity 7 and can be located inside of at least the individual information region 2. In addition, from the viewpoint of productivity, it is desirable that the base film 8 also serve as a protective film for the substrate 1. Considering Fresnel reflection, according to the present disclosure, it is desirable that the difference between the refractive index of the flow passage forming member and the refractive index of the base film be 0.3 or higher. As a result, more light is reflected from the base film 8, resulting in improvement of visibility. Furthermore, if the refractive index of the base film is 1.9 or higher, more light is reflected from the base film 8, which is desirable.

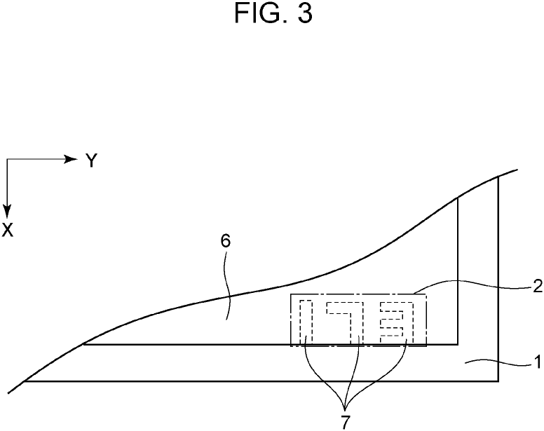

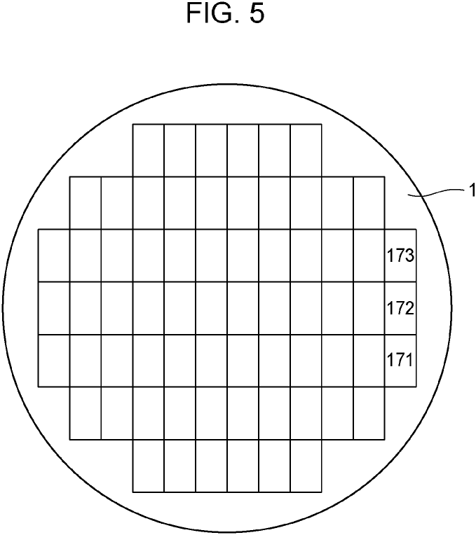

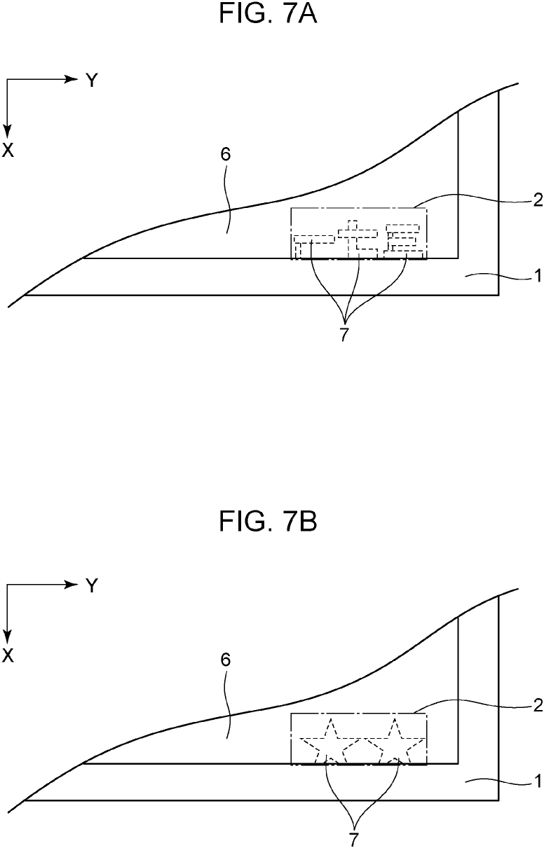

FIG. 3 is a schematic top view of the individual information region 2 illustrated in FIG. 2 as viewed from the positive Z direction. As illustrated in FIG. 3, the individual information region 2 is located so that the cavity 7 is in contact with an end portion of the flow passage forming member 6. However, the cavity 7 does not necessarily have to be in contact with the end portion of the flow passage forming member 6, and it is only required that the cavity 7 communicates with the atmosphere (open to the atmosphere) so that the cavity 7 can be formed at a later time. According to the present embodiment, as an example, the cavity 7 has the shape of a number representing the individual information. However, the shape is not limited thereto. For example, as illustrated in FIGS. 7A and 7B, characters or marks may be used as long as they have shapes recognizable from above. As an example of the individual information, the individual information may indicate the position of the print element substrate 11 in the substrate 1 (refer to FIG. 5). However, the individual information may include inspection information and measurement information in the process. In addition, to facilitate visual recognition of the individual information in the shape of the cavity 7, the individual information region 2 is provided with a base film (not illustrated) having a refractive index that is higher than at least the refractive index of the flow passage forming member 6. As a result, the reflection coefficients at the boundary planes between the cavity 7 and the base film 8 and between the flow passage forming member 6 and the base film 8 increase, so that the shape of the cavity 7 can be clearly seen. The reflected light increases with increasing reflection coefficient and, thus, the brightness increases, resulting in improved visibility.

It is desirable that the refractive index of the flow passage forming member 6 be lower than the refractive index of the base film 8. This is because when the refractive index of the flow passage forming member 6 is higher than the refractive index of the base film 8, a light ray entering the flow passage forming member from above is greatly refracted, resulting in reduced visibility. To avoid the reduced visibility, it is desirable that the refractive index of the flow passage forming member 6 be minimized.

In addition, it is desirable that the angle formed by the side surface of the cavity 7 and the substrate 1 is in a range of 85° to 95°. This is because by forming the side surface of the cavity 7 substantially perpendicularly to the substrate 1, the extra space can be reduced that is provided between adjacent pieces of individual identification information and that is required when the side surface of the cavity 7 is tilted. Thus, the cavity pattern can be densely packed.

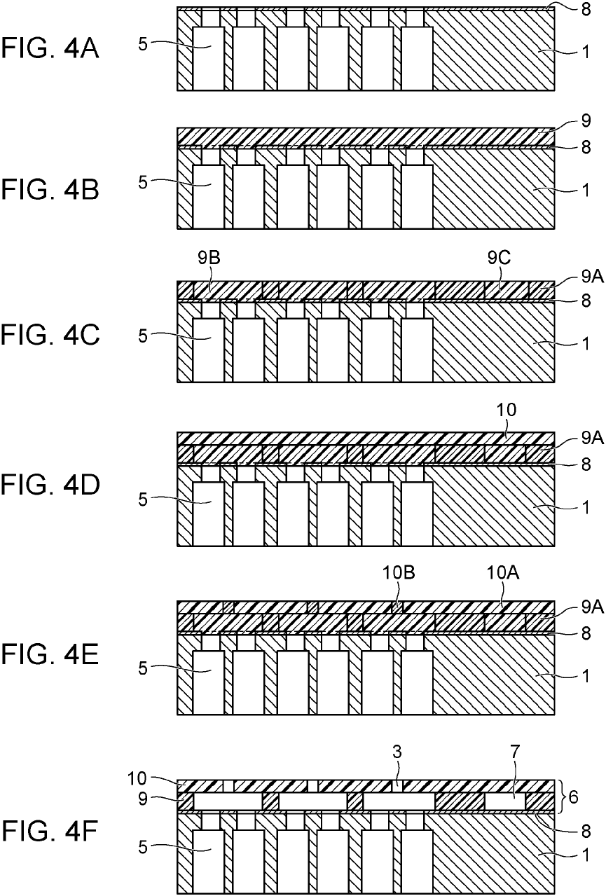

A method for manufacturing the print element substrate according to the present embodiment is described below with reference to FIGS. 4A to 4F. As illustrated in FIG. 4A, the substrate 1 having the base film 8 serving as both an energy generating element and a substrate protective film is prepared, and the liquid supply ports 5 are formed so as to penetrate the substrate 1. Subsequently, as illustrated in FIG. 4B, a first flow passage forming member 9 made of a negative photosensitive resin is formed on the surface of the substrate 1 having the base film 8 formed thereon. Subsequently, as illustrated in FIG. 4C, the first flow passage forming member 9 is subjected to i-line exposure through a photomask to optically determine a portion 9A that later serves as a flow passage wall, a portion 9B that later serves as a flow passage, and a portion 9C that later serves as the cavity that does not communicate with the flow passage. At this time, the first flow passage forming member 9 is a negative photoresist, and the flow passage wall that is almost vertical is formed by adjusting the exposure focus in exposure using the i-line stepper exposure method. Subsequently, as illustrated in FIG. 4D, a second flow passage forming member (an ejection port forming member) 10 made of a negative photosensitive resin is formed on the first flow passage forming member 9. Subsequently, as illustrated in FIG. 4E, the second flow passage forming member 10 is subjected to i-line exposure through a photomask to optically determine a portion 10A that later serves as a flow passage wall and a portion 10B that later serves as the ejection ports. Subsequently, as illustrated in FIG. 4F, the unexposed portions shielded by the photomask are removed by using a solvent capable of removing the unexposed portions of the flow passage forming member 6. Thus, the flow passage 4, the ejection ports 3, and the cavity 7 are formed.

Thereafter, the wafer is divided into chips, and each of the chips is mounted on a member for supplying liquid. In this manner, the print element substrate is achieved. While the present embodiment has been described with reference to the base film formed over the entire surface of the substrate to also serve as a protective film of the substrate, the present embodiment is not limited thereto. The base film is only required to be formed in at least the individual information region. In addition, while the present embodiment has been described with reference to a second flow passage wall forming member formed when a first flow passage wall forming member is an optically latent image, only the flow passage wall portion of the first flow passage forming member may be formed in advance, and the second flow passage forming member may be formed thereon.

### Exemplary Embodiment

An exemplary embodiment of the method for manufacturing the print element substrate according to the present disclosure is described with reference to FIGS. 4A to 4F. A plurality of liquid energy generating elements (not illustrated) were arranged on the substrate 1 illustrated in FIG. 4A, and the base film 8, which also served as an insulating protective film, was formed on the substrate 1. Thereafter, a mask resist was formed on the base film 8. After patterning was performed, the substrate 1 was processed by dry etching to form the liquid supply ports 5. A silicon substrate was used as the substrate 1. After formation of an SiO or SiN film by plasma CVD, an SiCN film was formed as the base film 8. The base film 8 formed at this time had a refractive index of 2.4.

Subsequently, as illustrated in FIG. 4B, the first flow passage forming member 9 made of a negative photosensitive resin was formed on the base film 8 by using the first flow passage forming member 9 formed on a support member into a dry film and a dry film transfer technique. At this time, the thickness of the first flow passage forming member 9 was 10 µm. As a transfer apparatus, VTM-200 (trade name, available from Takatori Corporation) was used. As the negative photosensitive resin, a mixture of 100 parts by mass of the epoxy resin EHPE3150 (trade name, available from Daicel Chemical Industries, Ltd.), 6 parts by mass of the photocationic polymerization catalyst SP-172 (trade name, available from ADEKA Corporation), and 20 parts by mass of the binder resin jER1007 (trade name, available from Mitsubishi Chemical Corporation) was used. As the support member for a dry film resist, a release treated PET film was used. The transfer temperature was 70° C., and the pressure was 0.5 MPa. The peeling speed of the support member was 5 mm/s.

Subsequently, as illustrated in FIG. 4C, the portion 9A of the first flow passage forming member 9, which later served as the flow passage wall, was exposed to an i-line wavelength of 365 nm through a photomask by using FPA-5510iV available from CANON KABUSHIKI KAISHA. Thereafter, post exposure bake (PEB) was carried out. The exposure dose was set to 8000 J/m2. In the PEB, heat was applied by using a hot plate at 50° C. for 4 minutes to accelerate the curing reaction. The portion 9B, which later served as the flow passage, and the portion 9C, which later served as the cavity not communicating with the flow passage, were shielded from light by a photomask, so that the curing reaction did not proceed. The portion 9C, which later served as the cavity, was disposed so as to be in contact with an end of the flow passage wall. In addition, by setting the exposure focus at a position half the thickness of the first flow passage forming member, the side wall of the cavity was formed substantially perpendicular to the substrate 1.

Subsequently, as illustrated in FIG. 4D, the second flow passage forming member (the ejection port forming member, a second dry film) 10 made of a negative photosensitive resin in the form of a dry film was formed on the first flow passage forming member 9 (the first dry film) so as to have a thickness of 10 µm. As the negative photosensitive resin, a mixture of 100 parts by mass of epoxy resin EHPE3150 (trade name, available from Daicel Chemical Industries, Ltd.) and 3 parts by mass of a photocationic polymerization initiator onium salt was used. Note that the onium salt has higher photosensitivity than the photocationic polymerization catalyst SP-172 used for the flow passage forming member and is able to generate cations from low exposure dose. As a support member for the dry film resist, a release treated PET film was used. The temperature for transferring the ejection port forming member was set to 40° C., and the pressure was set to 0.3 MPa. The peeling speed of the support member was 5 mm/s. A thickness of 2 µm to 11 µm can be suitably applied to the ejection port forming member.

Subsequently, as illustrated in FIG. 4E, the portion of the second flow passage forming member 10 that later served as the flow passage wall was exposed to an i-line wavelength of 365 nm by using FPA-5510iV (a reduction projection exposure apparatus available from CANON KABUSHIKI KAISHA). Thus, the portion 10A which later served as the flow passage wall and the portion 10B which later served as the ejection port were optically determined.

The exposure dose was set to 1000 J/m2. Although the unexposed portion of the first flow passage wall forming member was also irradiated with light, exposure of the second flow passage forming member did not cause curing reaction by adjusting the photosensitivity of the material. Thereafter, in PEB, heat was applied by using a hot plate at 90° C. for 5 minutes to accelerate the curing reaction.

Subsequently, as illustrated in FIG. 4F, the unexposed portions of the first flow passage forming member 9 and the second flow passage forming member 10 were simultaneously removed by a development process, and the flow passage 4, the ejection port 3, and the cavity 7 were formed. Propylene glycol monomethyl acetate was used as a solvent capable of dissolving the unexposed portions. Thereafter, baking was performed at 200° C. to complete the reaction of the epoxy resin. The refractive index of the flow passage forming member 6 formed at this time was 1.6.

Through the above-described steps, a substrate used as the print element substrate was achieved that had, formed therein, a nozzle portion for ejecting, from the ejection port 3, liquid flowing from the liquid supply port 5 through the flow passage 4 and the cavity 7 providing individual information. Then, the substrate was cut and separated into chips by a dicing saw or the like, electrical wiring lines for driving the liquid energy generating element were joined to each of the chips, and finally, a chip tank member for supplying liquid was joined. In this way, the print element substrate was achieved. When viewing an individual identification information section of the print element substrate, the individual identification information section had excellent visibility even if the side surface of the cavity was almost vertical.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-069953 filed Apr. 21, 2022, which is hereby incorporated by reference herein in its entirety.

What is claimed is:

1. A print element substrate comprising:
a substrate including an energy generating element configured to generate energy for ejecting liquid from an ejection port; and
a flow passage forming member including a flow passage configured to supply the liquid to the ejection port,
wherein the flow passage forming member includes, formed therein, a cavity not communicating with the flow passage,
wherein a side surface of the cavity is formed substantially perpendicular to the substrate,
wherein a base film is formed between the cavity and the substrate,
wherein a refractive index of the flow passage forming member is lower than a refractive index of the base film, and
wherein a difference between the refractive index of the flow passage forming member and the refractive index of the base film is greater than or equal to 0.3.

2. The print element substrate according to claim 1, wherein an angle formed by the side surface of the cavity and the substrate is in a range of 85° to 95°.

3. The print element substrate according to claim 1, wherein the refractive index of the base film is higher than or equal to 1.9.

4. The print element substrate according to claim 1, wherein the base film is a protective film of the substrate.

5. The print element substrate according to claim 1, wherein the cavity is open to an atmosphere.

6. The print element substrate according to claim 1, wherein an ejection port forming member configured to form the ejection port is formed on the flow passage forming member, and
wherein a thickness of the ejection port forming member is in a range of 2 µm to 11 µm.

7. A method for manufacturing a print element substrate, the print element substrate including a substrate including an energy generating element configured to generate energy for ejecting liquid from an ejection port and
a flow passage forming member including a flow passage configured to supply the liquid to the ejection port and a cavity not communicating with the flow passage,
the method comprising:
preparing the substrate having a base film;
forming the flow passage forming member on the substrate;
forming a first dry film on the substrate, wherein the first dry film later serves as the flow passage forming member;
forming latent images of portions of the first dry film that later serve as the flow passage and the cavity;
forming a second dry film on the first dry film, wherein the second dry film later serves as an ejection port forming member;
forming a latent image of a portion of the second dry film that later serves as the ejection port;
developing the first dry film to form the flow passage and the cavity;
developing the second dry film to form the ejection port,
wherein the base film is formed between the substrate and the cavity,
wherein a refractive index of the flow passage forming member is lower than a refractive index of the base film, and
wherein a difference between the refractive index of the flow passage forming member and the refractive index of the base film is greater than or equal to 0.3.

8. The method according to claim 7, wherein the first dry film is made of a negative photosensitive resin.

9. The method according to claim 7, wherein the second dry film is made of a negative photosensitive resin.

10. The method according to claim 7, wherein a reduction projection exposure apparatus is used when the first dry film is developed.

11. The method according to claim 7, wherein after the first dry film is developed, the second dry film is formed on the first dry film.

12. The method according to claim 7, wherein development of the first dry film and development of the second dry film are simultaneously performed.

13. The method according to claim 7, wherein the cavity is open to an atmosphere.

14. The method according to claim 7, wherein the refractive index of the base film is higher than or equal to 1.9.

15. The method according to claim 7, wherein the base film is a protective film of the substrate.

16. The method according to claim 7, wherein a thickness of the ejection port forming member is in a range of 2 µm to 11 µm.
